(19) United States
(12) Patent Application Publication
(10) Pub. No.: US 2013/0302989 A1
(43) Pub. Date: Nov. 14, 2013

(54) REDUCING LINE EDGE ROUGHNESS IN HARDMASK INTEGRATION SCHEMES

(71) Applicants: Oisin Kenny, Dresden (DE); Torsten Huisinga, Dresden (DE)

(72) Inventors: Oisin Kenny, Dresden (DE); Torsten Huisinga, Dresden (DE)

(73) Assignee: GLOBALFOUNDRIES INC., Grand Cayman (KY)

(21) Appl. No.: 13/466,215

(22) Filed: May 8, 2012

(51) Int. Cl. H01L 21/768

(52) U.S. Cl. 438/700; 257/E21.579

(57) ABSTRACT

Generally, the present disclosure is directed to methods for reducing line edge roughness in hardmask integration schemes that are used for forming interconnect structures, such as conductive lines and the like. One illustrative method disclosed herein includes, among other things, forming a metal hardmask above a dielectric material and forming a first opening in the metal hardmask, the first opening comprising sidewalls, and the sidewalls having a surface roughness. The disclosed method further includes reducing the surface roughness of the sidewalls, and using the first opening with the sidewalls of reduced surface roughness to form a second opening in the dielectric material.

### BACKGROUND OF THE INVENTION

1. Field of the Invention

Generally, the present invention relates to sophisticated integrated circuits, and, more particularly, to reducing line edge roughness in hardmask integration schemes that are used for forming interconnect structures such as conductive lines and the like.

2. Description of the Related Art

In a typical integrated circuit, a very large number of circuit elements, such as transistors, capacitors, resistors and the like, are formed in and/or above an appropriately configured substrate, such as a semiconductor substrate. Due to the large number of circuit elements that may be formed, and the complexity of the layout that is oftentimes required for such advanced integrated circuits, the electrical connections of the individual circuit elements are generally not established within the same level of a given semiconductor chip in which the circuit elements are formed, sometimes referred to as the device level of the chip. Typically, such electrical connections are formed in a plurality of additional stacked wiring layers, also referred to as metallization layers, that are formed above the device level, and which, taken together, may sometimes be referred to as a metallization system. In many applications, these stacked metallization layers each include a plurality of substantially horizontally routed conductive lines, which may provide intra-level electrical connections, i.e., connections to other circuit elements within a given metallization layer. Furthermore, each of the various metallization layers may also include a plurality of substantially vertically routed conductive vias, which provide inter-level connections to circuit elements positioned in adjacent metallization layers. Commonly, the conductive lines and conductive vias are generically referred to as interconnect structures or electrical interconnects.

In modern semiconductor devices, the feature sizes of integrated circuit elements have been continuously reduced with the introduction of each new device design generation. At present, circuit elements are routinely formed having critical dimensions of 50 nm, and even less, thereby providing an enhanced degree of device performance in terms of speed and/or power consumption. Furthermore, as the overall dimensions of circuit elements, particularly transistor elements, have decreased, the packing density of those elements has been commensurately increased, thus providing the potential for incorporating increased functionality into a given area of a semiconductor chip. However, while decreased feature sizes and increased device packing density have generally been beneficial, a variety of device processing issues have arisen in conjunction with these size-related trends that can have a substantial impact on device reliability and/or device yield.

For example, as the overall size of transistor elements has steadily been reduced, the size of and spacing between the various interconnect structures, such as conductive lines and conductive vias, used to form the electrical circuit layout of a given device have also been reduced to keep pace, due at least in part to the increased packing density of the various circuit elements, as well as the additional circuit complexity that may be associated with increased chip functionality. These reduced-size interconnect structures may therefore typically be operated at significantly increased current densities of up to several kA per cm² in an individual interconnect structures, even in those instances where a relatively large number of metallization layers may be used due to the high number of circuit elements per unit area. Operating interconnect structures at such elevated current densities may entail a plurality of problems related to stress-induced line degradation, such as electromigration, which may lead to a premature failure of the integrated circuit.

Consequently, as the feature sizes steadily decrease, and as the current density in respective interconnect structures commensurately increases, copper and copper alloy materials have increasingly replaced aluminum as the material of choice for forming interconnect structures in metallization layers. This is due at least in part copper's lower electrical resistivity, as well as its greater resistance to electromigration effects even at considerably higher current densities, as compared to aluminum. However, the use of copper-based metallization layers also presents additional device processing issues that can increase overall processing complexity. For example, unlike aluminum-based metallization layers, copper-based metallization layers are typically formed using a so-called damascene or inlaid technique, due to copper's general inability to form volatile etch products when being exposed to well-established anisotropic etch ambients. Furthermore, copper may also not be deposited with high deposition rates on the basis of well-established deposition techniques that might typically be used for depositing aluminum-based materials, such as chemical vapor deposition (CVD). Therefore, rather than patterning an aluminum material layer so as to define the circuit layout in a given aluminum-based metallization layer, in the damascene technique, a layer of dielectric material is patterned to receive trenches (for conductive lines) and/or via openings (for conductive vias), which are subsequently filled with the copper-based material by an efficient electrochemical deposition technique, such as electroplating and the like.

Additionally, as the critical dimensions of circuit elements are reduced, e.g., conductive line widths of 50 nm or even less, various process-related issues associated with using the damascene technique to form interconnect structures in respective dielectric material layers may also arise, as will be described in detail with respect to FIGS. 1a-1e below.

FIGS. 1a-1e schematically depict a representative prior art processing approach that has been used for forming interconnect structures based on a damascene, or inlaid, technique. More specifically, FIG. 1a is a schematic cross-sectional view of a semiconductor device 100 that includes a dielectric material 101 in which one or more interconnect structures, such as a conductive via and/or a conductive line, may be formed during later processing stages. A dielectric cap layer 102 is formed above the dielectric material 101, and an etch mask 103 is formed above the dielectric cap layer 102. As shown in FIG. 1a, the etch mask 103 has been patterned using conventional patterning techniques well known in the art so as to include a plurality of openings 104, which, during a later manufacturing step, will be transferred into the dielectric material 101 using a suitably designed etch process, so as to thereby form trench openings (for conductive lines) and/or via openings (for conductive vias) in the dielectric material 101. In some cases, the dielectric cap layer 102 acts as an etch stop layer during the patterning operation of the etch mask 103. Typically, the openings 104 are formed in the etch mask 103 so as to have a width, or critical dimension, 105, and a pitch 105p between adjacent openings 104. Furthermore, the edges, or sidewalls, 104e, of an individual opening 104 are separated from the sidewalls 104e of the adjacent openings 104 on either side thereof by a space 106.

As noted above, as the feature sizes of circuit elements are steadily reduced, the critical dimensions of interconnect structures, as well as the spacing therebetween, have also been steadily reduced, due to the greater overall packing density of the circuit elements. For example, the critical dimension, i.e., the width, of some interconnect structures may be as small as 50 nm or even less. In such cases, the need to maintain the dimensional stability of the patterned openings 104 throughout the etch process that is used to form the trench and/or via openings in the dielectric material 101 can become more important, as dimensional variations in width and/or spacing of such reduced-size elements can have a proportionally greater effect on the quality and performance of the finished devices. Accordingly, in many applications, a metal hardmask, such as a titanium nitride metal hardmask and the like, is typically used as the etch mask 103, which, depending on the specific etch recipe used to form the trench and/or via openings, is sometimes able to substantially maintain a greater degree of dimensional stability and edge definition throughout the etch process, as compared to, for example, a photoresist mask and the like. However, in spite of being able to substantially maintain dimensional stability during a subsequent etch process, the use of a metal hardmask as the etch mask 103 can sometimes present different size-related processing difficulties relative to the width 105 of the patterned openings 104 and the space 106 therebetween, as will be further discussed below.

In some cases, the inherent limitations of modern lithography and etching processes that are typically used to pattern the openings 104 may lead to a certain degree of line edge roughness (LER) along the sidewalls 104e. FIG. 1b is a close-up section view—i.e., along the section line “1b-1b” shown in FIG. 1a—of a respective opening 104, e.g., a trench opening, that has been formed using conventional lithography and etching techniques, as previously described, which is schematically depicted as a serrated edge in an exaggerated fashion in FIG. 1b.

In some instances, the degree of line edge roughness can be exacerbated by the material properties of the metal material that is used to form the metal hardmask 103, such as the grain size of the metal material, its resistance to the etch recipe used to form the openings 104, and the like. Moreover, the line edge roughness of the sidewalls 104e can sometimes be transferred to an increased degree to the underlying dielectric material 101, which can potentially lead to significant dimensional variations of at least some of the trench and/or via openings that are subsequently formed when the patterned openings 104 are transferred to the dielectric material 101, as shown in FIGS. 1c-1e and described below.

FIG. 1c schematically illustrates the semiconductor device 100 after an anisotropic etch process 121, such as a reactive ion etch (RIE) process, has been performed so as to transfer the patterned openings 104 into the underlying dielectric material 101, thereby forming openings 107, e.g., trench openings, in the dielectric material 101. During the etch process 121, the cap/etch stop layer 102 is selectively etched first, after which the etch recipe of the etch process 121 is typically adjusted so as to selectively etch the openings 107. Typically, the width 105 of the openings 104 in the metal hardmask 103 and the space 106 between the openings 104 are established such that the openings 107 in the dielectric material 101 are formed having a nominal desired width 108 and a nominal desired space 109 between the edges, or sidewalls, 107e of adjacent openings 107.

FIG. 1d is a section view—i.e., along the section line “1d-1d” shown in FIG. 1c—of the trench openings 107. It should be noted that section line “1d-1d” is taken below the metal hardmask 103 and the cap layer 102, so that dimensional variations of the trench openings 107 formed in the dielectric material 101 can be more clearly viewed. As a result of the line edge roughness of the sidewalls 104e of the patterned openings 104 formed in the metal hardmask 103, local variations of the actual width, or critical dimension, of the trench openings 107 relative to the nominal desired width 108 may be present. Furthermore, the actual size of the space between the sidewalls 107e may also locally vary from the nominal desired space 109. For example, as shown in FIG. 1d, in some locations a respective trench opening 107 can have a width 108w that is wider than the desired nominal width 108. This in turn can lead to an adjacent space 109n that is narrower than the desired nominal space 109. In other locations, a respective trench opening 107 can sometimes have a width 108n that is narrower than the desired nominal width 108, which, similarly, can result in an adjacent space 109w that is wider than the desired nominal space 109. Such irregularities in the respective dimensions of a given trench opening 107 can lead to a reduction in product yield and/or premature device failures, as described below.

FIG. 1e schematically depicts the semiconductor device 100 as shown in the plan view of FIG. 1d after a conductive material has been formed in the trench openings 107 so as to thereby form conductive lines 110 having nominal line widths 111, but which also have locally varying widths. For example, in some cases, an actual trench width 108w (see, FIG. 1d) that is greater than the nominal desired trench width 108 may result in a locally increased line width 111w and commensurately decreased size of the local space 111s between adjacent lines 110. Such configurations can result in a reduced line-to-line electrical isolation, which can in turn lead to an increased likelihood of time dependent dielectric breakdown (TDDB) failures of the semiconductor device 100. On the other hand, the presence of a locally increased trench width 108w can sometimes have a detrimental effect, at least locally, on the effectiveness of the deposition process that is used to fill the trench opening 107. This local deposition effect can result in a localized trench pinch-off region 112, wherein the local line width 111n is less than the trench width 108w, and less than the width 111 of the adjacent portions of the line 110. Furthermore, this trench pinch-off phenomenon can lead to the formation of line voids 111v, resulting in a reduction in product yield, or premature electromigration-related device failures.

FIGS. 1f-1g are photomicrographs of representative prior art semiconductor devices (such as the semiconductor device 100 shown in FIGS. 1a-1b) that have been included herein for illustrative purposes so as to show some aspects of the prior art processes and devices described above. More specifically, FIG. 1f shows several photomicrographs illustrate shows a plurality of trench openings (such as the trench openings 104) that have been formed in a metal hardmask (such as the metal hardmask 103 as shown in FIGS. 1a-1b). Furthermore, FIG. 1f illustrates the type of line edge roughness (LER) that may typically be present along the sidewalls of the trench openings (such as the sidewalls 104e shown in FIGS. 1a-1b) when conventional patterning techniques are used to form the trench openings 104. Areas 150 where excessive line edge roughness can potentially lead to device reliability failures have been highlighted in FIG. 1f.

FIG. 1g shows photomicrographs illustrating a plurality of representative conductive lines (such as the conductive lines 110 shown in FIG. 1e) formed in a dielectric material (such as the dielectric material 101 of FIGS. 1a-1e), wherein conductive line defects and/or areas of potential device reliability failures are present. More specifically, FIG. 1g shows a reduced-size space (such as the reduced-size space 111s of FIG. 1e) between adjacent conductive lines 110a/b and 110d/e, which typically result from a locally increased line width (such as the locally increased line width 111w). Also shown in FIG. 1g are localized trench pinch-off regions (such as the trench pinch-off region 112 of FIG. 1e) that can result from the presence of line voids (such as the line voids 111v) in the respective conductive lines 110c and 110e, as well as the locally reduced conductive line widths resulting therefrom (such as the reduced line width 111n of FIG. 1e).

The present disclosure is directed to various approaches for forming interconnect structures for semiconductor devices that may avoid, or at least reduce, the effects of one or more of the problems identified above.

### SUMMARY OF THE DISCLOSURE

The following presents a simplified summary of the present disclosure in order to provide a basic understanding of some aspects disclosed herein. This summary is not an exhaustive overview of the disclosure, nor is it intended to identify key or critical elements of the subject matter disclosed here. Its sole purpose is to present some concepts in a simplified form as a prelude to the more detailed description that is discussed later.

Generally, the present disclosure is directed to methods for reducing line edge roughness in hardmask integration schemes that are used for forming interconnect structures, such as conductive lines and the like. One illustrative method disclosed herein includes, among other things, forming a metal hardmask above a dielectric material and forming a first opening in the metal hardmask, the first opening comprising sidewalls, and the sidewalls having a surface roughness. The disclosed method further includes reducing the surface roughness of the sidewalls, and using the first opening with the sidewalls of reduced surface roughness to form a second opening in the dielectric material.

Another illustrative embodiment of the present disclosure is a method that includes forming a patterned metal hardmask above a dielectric material layer, the metal patterned hardmask including a patterned opening. Additionally, the method also includes, among other things, forming sidewall spacers on sidewalls of the patterned opening and using the sidewall spacers as an etch mask to form one of a trench opening and a via opening in the dielectric material layer below the patterned opening.

Also disclosed herein is a method that includes, among other things, forming a metal hardmask above a layer of dielectric material and forming a patterned opening in the metal hardmask so as to expose a portion of a cap layer formed above the layer of dielectric material, wherein the patterned opening has exposed sidewalls with a first surface roughness. The method further includes a step of forming a layer of spacer material at least on the exposed sidewalls of said patterned opening and above the exposed portion of said cap layer, and forming sidewall spacers on said the exposed sidewalls of the patterned opening from the layer of spacer material by removing at least a portion of the layer of spacer material from above the cap layer, wherein an exposed surface of the sidewall spacers has a reduced surface roughness as compared to the first surface roughness. Additionally, the disclosed method includes forming at least one of a trench opening and a via opening in the layer of dielectric material using the sidewall spacers as an etch mask.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1e schematically depict one illustrative prior art method that has been used for forming interconnect structures in semiconductor devices;

FIGS. 1f-1g are photomicrographs of representative prior art semiconductor devices that show some aspects of the prior art processes and devices described herein;

FIGS. 2a-2e schematically illustrate one illustrative method of reducing line edge roughness in a hardmask integration scheme used for forming interconnect structures in accordance with the present disclosure; and

FIGS. 3a-3c schematically illustrate another embodiment disclosed herein that may be used for forming interconnect structures using a hardmask integration scheme with reduced line edge roughness.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the present subject matter are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the subject matter of the present disclosure is directed to various methods for reducing line edge roughness in hardmask integration schemes that may be used for forming interconnect structures, such as conductive lines and the like, for semiconductor devices. In some embodiments, a thin liner layer may be formed at least on the sidewall surfaces of patterned openings that have been formed in a hardmask layer, such as a metal hardmask layer and the like, so as to thereby reduce the surface roughness along the edges or sidewalls of the patterned openings—i.e., to reduce the line edge roughness of the patterned openings in the hardmask layer. In certain embodiments, the thin liner layer may be formed using a deposition process that deposits material in a substantially conformal manner, which may at least partially “smooth out” rough surfaces that may be present on the edges of the patterned openings. The patterned openings having a reduced line edge roughness may then be used to form openings, such as trench and/or via openings, in an underlying dielectric material. In certain embodiments, the material of the liner layer may be selected so as to have a high etch selectivity relative to the underlying dielectric material. In this way, the trenches and/or via openings formed in the dielectric material during a subsequent etch process may have substantially smoother sidewalls, and substantially more uniform opening widths (i.e., critical dimensions), as compared to openings that may be formed in the dielectric material using an un-lined metal hardmask layer in accordance with the prior art methods described above.

In other illustrative embodiments, the material of the liner layer may be selected so as to have a lesser degree of etch selectivity relative to the dielectric material therebelow, which may thus lead to forming the openings in the dielectric material with a slightly enhanced tapered shape. This tapered opening shape may in turn increase overall product yield, as the tapered shape is generally considered to be a more fill-friendly profile when, for example, a physical vapor deposition (PVD) process is used to fill the openings. On the other hand, a tapered opening shape is typically much more difficult to achieve when using a metal hardmask without the conformal liner layer of the present disclosure, e.g., an unlined metal hardmask, as is commonly used in the prior art hardmask integration schemes.

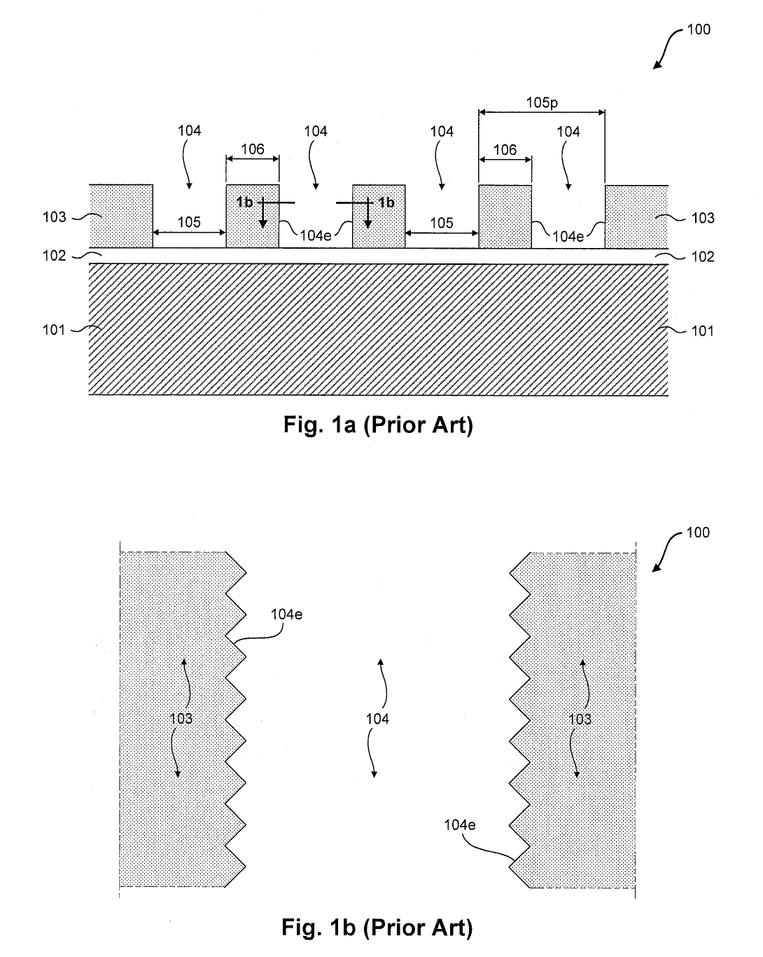

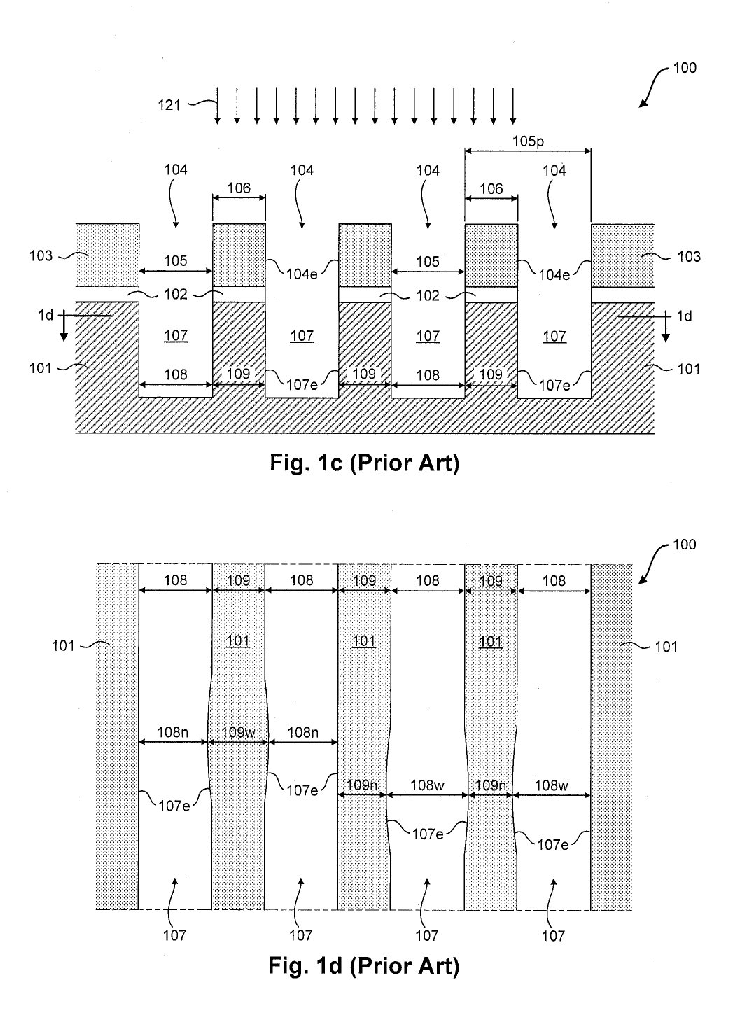

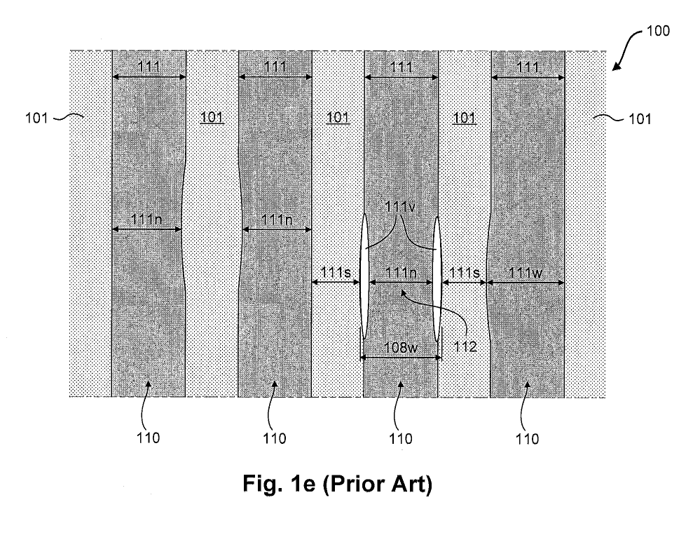

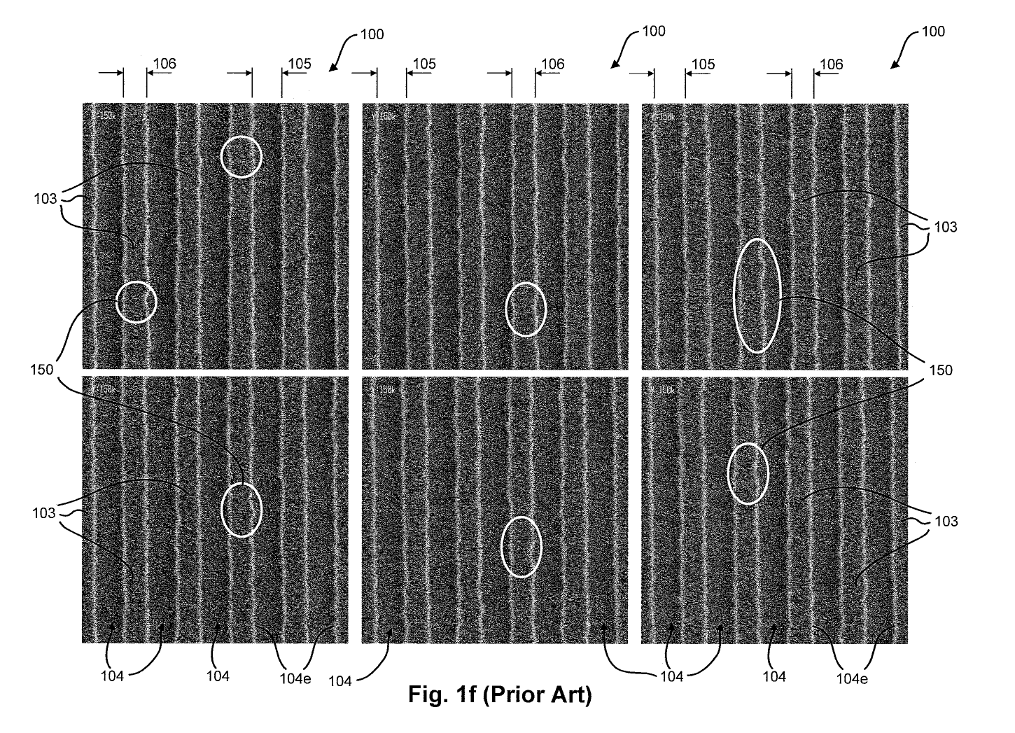

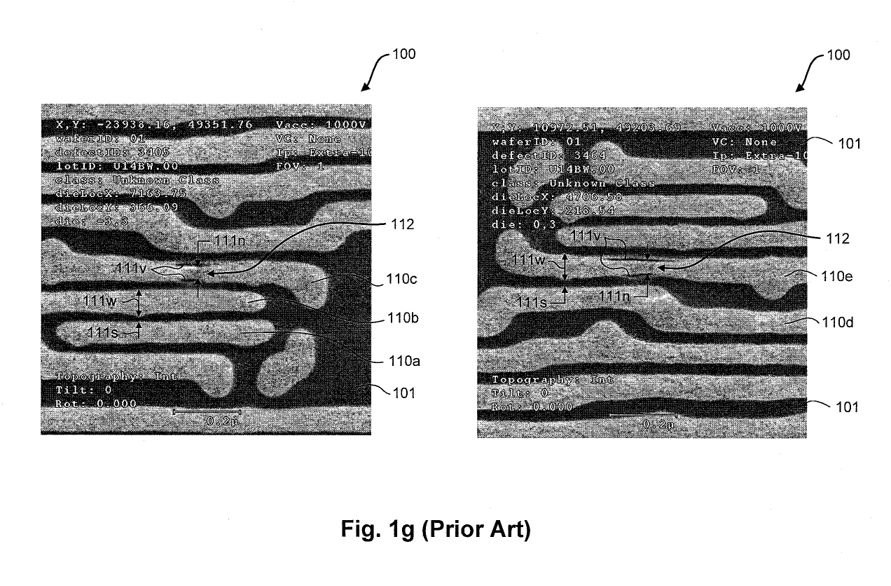

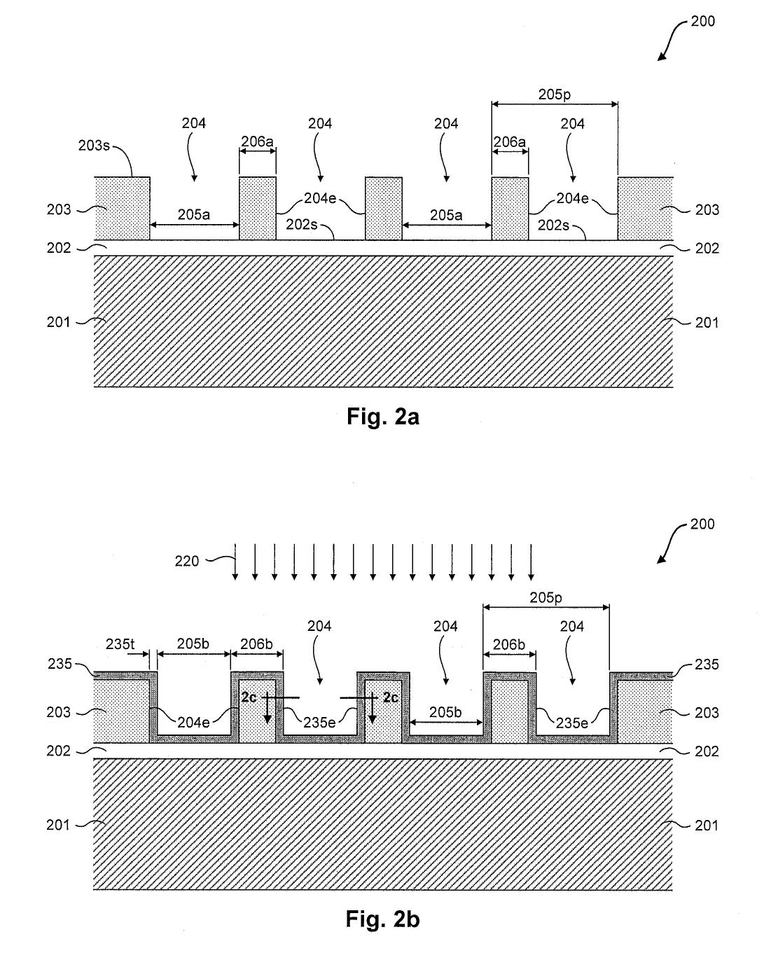

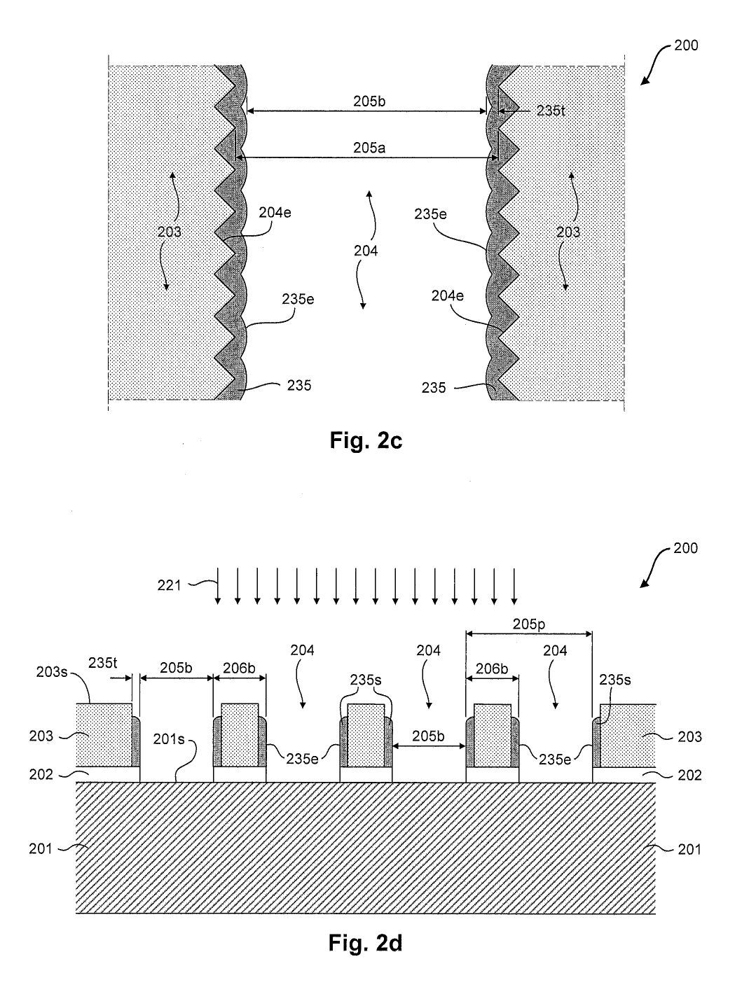

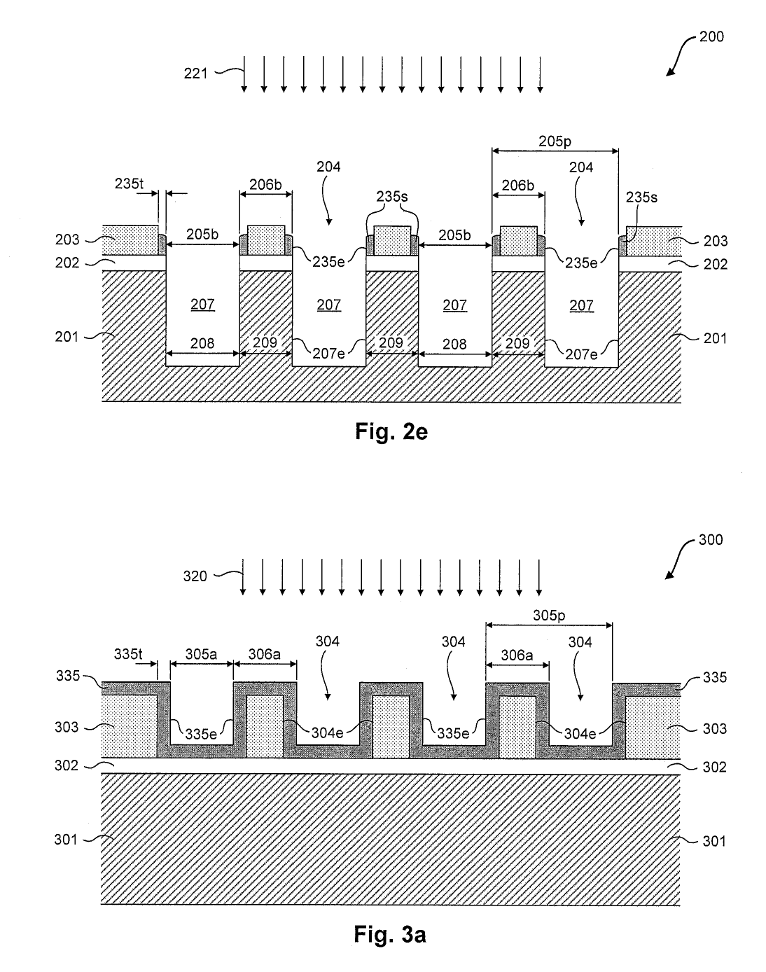

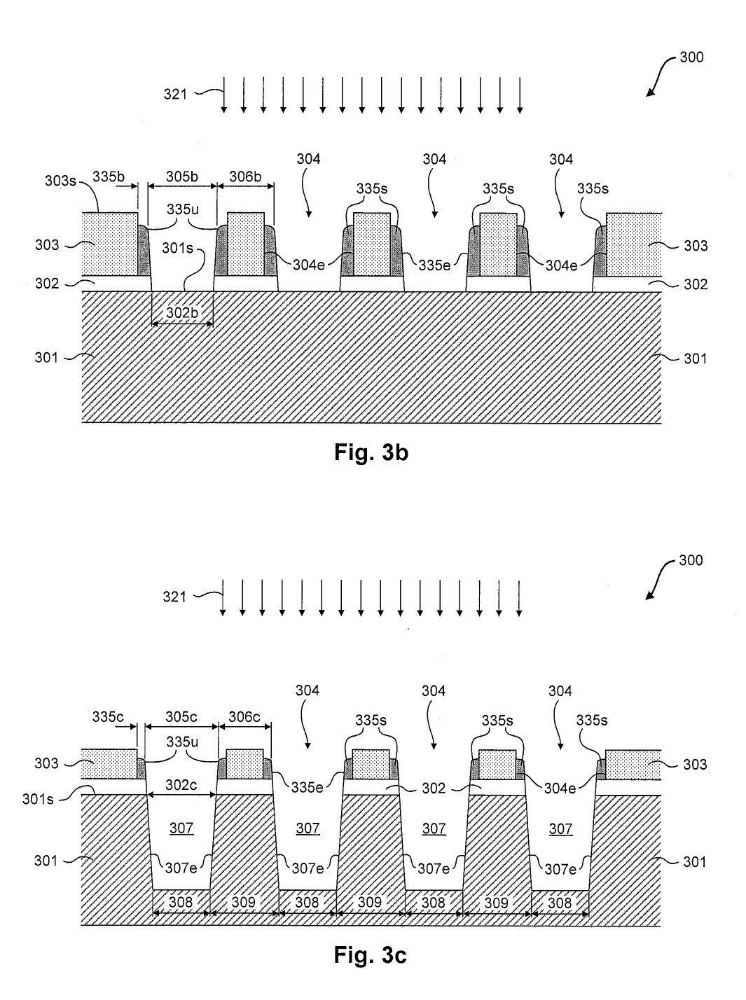

FIGS. 2a-2e and FIGS. 3a-3c, which schematically depict some of the illustrative embodiments of the present disclosure discussed above, will be described in further detail below. It should be noted that, where appropriate, the reference numbers used in describing the various elements shown in the illustrative embodiments of FIGS. 2a-2d and FIGS. 3a-3c may substantially correspond, where appropriate, to the reference numbers used in describing related elements illustrated in FIGS. 1a-1e above, except that the leading numeral in each figure has been changed from a “1” to a “2,” or from a “1” to a “3,” where appropriate. For example, the dielectric material “101” may substantially corresponds to the dielectric materials “201” and “301,” the patterned openings “104” may correspond to the patterned openings “204” and “304,” and so on. Accordingly, the reference number designations used to identify some elements of the presently disclosed subject matter may be illustrated in the FIGS. 2a-2e and FIGS. 3a-3c but may not be specifically described in the following disclosure. In those instances, it should be understood that the numbered elements shown in FIGS. 2a-2e and FIGS. 3a-3e which are not described in detail below substantially correspond with their like-numbered counterparts illustrated in FIGS. 1a-1e and described in the associated disclosure set forth above.

With respect to the descriptions of the various illustrative embodiments set forth herein, it should also be understood that, unless otherwise specifically indicated, any relative positional or directional terms that may be used in the descriptions below—such as “upper,” “lower,” “on,” “adjacent to,” “above,” “below,” “over,” “under,” “top,” “bottom,” “vertical,” “horizontal,” and the like—should be construed in light of that term's normal and everyday meaning relative to the depiction of the components or elements in the referenced figures. For example, referring to the schematic cross-section of the semiconductor device 200 depicted in FIG. 2a, it should be understood that the hardmask 203 is formed “above” the cap layer 202, and that the dielectric material 201 is positioned “below” or “under” the cap layer 202, and the patterned openings 204 are formed “in” the hardmask 203. Similarly, it should also be appreciated that in certain embodiments, the liner layer 235 is positioned “on” the sidewalls 204e of the patterned openings 204, whereas in other embodiments, the liner layer 235 may be positioned “adjacent to” the sidewalls 204e of the patterned openings 204 in those configurations where an additional layer or other structure may be interposed therebetween.

FIGS. 2a-2e shows various steps in one illustrative method for reducing the line edge roughness of patterned openings in hardmask integration schemes that may be used for forming interconnect structures in an underlying dielectric material. FIG. 2a schematically depicts an illustrative semiconductor device 200 during a manufacturing stage that is similar to that of the semiconductor device 100 shown in FIG. 1a. However, in the illustrative embodiment of the semiconductor device that is shown in FIG. 2a, the initial width 205a of the patterned openings 204 that are formed in the hardmask 203 may be different, e.g., in some cases, larger, than the corresponding openings 104 in the prior art device 100. For example, in some embodiments of the present disclosure, the nominal width, or critical dimension, of conductive features to be formed in the semiconductor device 200 may be substantially the same as the corresponding features of the prior art device 100. In such cases, the initial width 205a of the openings 204 may be greater than the width 105 of the prior art device 100, so as to compensate for the thickness of a liner layer that will subsequently be formed in the openings 204, at least a portion of which will remain in place along the sidewalls of the openings 204 during a later-performed patterning process that is used for forming trench and/or via openings in a dielectric material 201, as will be described in further detail below. See, e.g., the liner layer 235 shown in FIG. 2b and the sidewall spacer portions 235s shown in FIG. 2d-2e and described below.

In some illustrative embodiments, the openings 204 may be formed in the hardmask 203 based on a pitch 205p between adjacent openings 204 and having edges, or sidewalls, 204e that may be separated from the sidewalls 204e of adjacent openings 204 by a space 206a. Furthermore, in those embodiments wherein the width of conductive features to be formed on the semiconductor device 200 may be substantially the same as the corresponding features of the prior art device 100, the space 206a between adjacent sidewalls 204e may be reduced by an appropriate amount so that the pitch 205p between adjacent openings 204 may be substantially consistent with the pitch 105p of the prior art semiconductor device 100. In other embodiments, the space 206a may be adjusted as required such that the an actual space between adjacent conductive features may be based on the specific device design parameters for the respective conductive features that will be formed during a later manufacturing stage, such as, for example, an acceptable level of parasitic resistive capacitance, and the like.

In at least some embodiments of the present disclosure, the hardmask 203 may be, for example a metal hardmask, such as titanium nitride and the like. It should be understood, however, that the hardmask 203 need not be a metal hardmask as noted with respect to the prior art methods described above. On the contrary, the techniques described herein are not so limited, as it should be appreciated by a person of ordinary skill after a complete reading of the present disclosure that the hardmask 203 may be made up of any suitable hardmask material that can be used for forming trench and/or via openings in and underlying dielectric layer, such as the dielectric material 201. For example, in certain embodiments, the hardmask 203 may be any well-known dielectric hardmask material, such as silicon nitride and the like, and depending on the etch selectivity requirements of the underlying material layers. Other appropriately selected hardmask materials may also be used. However, for purposes of simplicity, and unless otherwise specifically indicated, the hardmask 203 shall hereinafter be referred to as a metal hardmask 203.

As shown in FIG. 2a, the metal hardmask 203 may be formed above a cap layer 202. In some illustrative embodiments, conventional patterning techniques may be used as previously described so as to form the openings 204 in the metal hardmask 203 and to expose an upper surface 202s of the cap layer 202, which, in certain embodiments, may be used as an etch stop layer during the patterning process. The cap layer 202 may in turn be formed above a dielectric material 201, which may represent any layer of dielectric material in which interconnect structures, such as conductive lines and/or conductive vias, may be formed, illustrative examples of which are well-known in the art. For example, in at least some embodiments, the dielectric material 201 may represent an interlayer dielectric (ILD) material, which may be formed above a device layer (not shown) of the semiconductor device 200. In such cases, the ILD material, i.e., the dielectric material 201, may be formed so as to electrically isolate one or more integrated circuit elements (not shown) that may be formed in the device layer, such as transistor elements and the like. Furthermore, in those illustrative embodiments wherein the dielectric material 201 represents an ILD material, the subsequently formed interconnect structures may configured so as to provide electrical connections between the integrated circuit elements in the device layer and a first metallization layer (not shown) formed above the interlayer dielectric material during back-end-of-line (BEOL) device processing.

In other embodiments, the dielectric material 201 may be representative of a dielectric material layer that may be any one of a plurality of BEOL metallization layers (not shown) formed above an ILD material, wherein respective interconnect structures, such as conductive lines and/or conductive vias, may be formed so as to define the overall integrated circuit layout (not shown) of the semiconductor device 200. Furthermore, it should be appreciated that the dielectric material 201, whether an ILD material or a metallization layer, may be made up of one or more dielectric materials and/or material sub-layers, depending on the overall device design and layout requirements. For example, in certain embodiments, the dielectric material 201 may be made up of any one of a variety of well-known silicon-based dielectric materials, such as a silicon dioxide, silicon nitride, and/or silicon oxynitride material. In other embodiments the dielectric material 201 may also include so-called “low-k” dielectric materials, e.g., materials having a dielectric constant “k” of less than approximately 3.0, examples of which may include organic and/or inorganic materials. Other material types may also be used for the dielectric material 201.

FIG. 2b illustrates the semiconductor device 200 of FIG. 2a in a further advanced manufacturing stage, wherein a liner layer 235 has been formed above the metal hardmask 203. In at least some embodiments, the liner layer 235 may be formed in a highly conformal manner above an upper surface 203s (see, FIG. 2a) of the metal hardmask 203, along the sidewalls 204e of the openings 204, and along the bottom of the openings 204, e.g., above the exposed upper surface 202s (see, FIG. 2a) of the cap layer 202. Depending on the specific device processing requirements, the liner layer 235 may be formed using a suitably designed deposition process 220, which, in certain embodiments may be, for example, a highly conformal material deposition process, such as a chemical vapor deposition (CVD) process or an atomic layer deposition (ALD) process, and the like.

As noted previously, the initial width 205a (see, FIG. 2a) of the patterned openings 204 may be adjusted as necessary so as to account for the presence of the liner layer 235 during subsequent processing steps. For example, as shown in FIG. 2e and described in further detail below, in some embodiments disclosed herein, the specific integration scheme may require that the openings 207, e.g., trench and/or via openings, that will be formed in the dielectric material 201 during subsequent processing steps may have a desired width, or critical dimension, 208. In such embodiments, the initial width 205a of the patterned openings 204 formed in the metal hardmask 203 and that will be used to form the openings 207 may be wider than the width 208 by approximately 2 times the liner thickness 235t (see, FIG. 2b). Therefore, as shown in FIG. 2b, after the liner layer 235 has been formed above the metal hardmask 203, the patterned openings 204 may have a reduced width 205b that is less than the initial width 205a by approximately twice the liner thickness 235t, e.g., a width that is approximately the same as that of the desired target width 208 of the openings 207.

Accordingly, in those embodiments wherein the desired target width 208 of the openings 207 that are to be formed in the dielectric material 201 may be substantially the same as the nominal width 108 of the openings 107 formed in the prior art semiconductor device 100, it should be appreciated that only minor adjustments to the overall prior art integration scheme may be necessary so as to increase the opening width 205a above that of the openings 105 in the prior art device 100. Such a minor change in the width 205a of the patterned openings 204, e.g., by an amount that is equal to approximately twice the liner thickness 235t, would not normally tend to have much of an impact, if any, on overall device cost and/or processing time in comparison to the prior art process described above.

FIG. 2c is a close-up section view—i.e., along the section line “2c-2c” shown in FIG. 2b—of a respective opening 204, for example a trench opening, after the liner layer 235 has been formed in the openings 204 and above the metal hardmask 203. FIG. 2c schematically illustrates the surface roughness, i.e., the line edge roughness, of the sidewalls 204e of the patterned openings 204 in an exaggerated fashion, wherein, the line edge roughness of the sidewalls 204e may be substantially similar to the line edge roughness of the sidewalls 104e in the prior art device 100 described above. However, as shown schematically in FIG. 2c, the surface roughness along the sidewalls 235e of the liner layer 235 has been substantially reduced (i.e., the surface smoothness has been substantially enhanced) as compared to that of the opening sidewalls 204e, due at least in part to the conformal nature of the liner layer 235. Accordingly, the reduced surface roughness, or enhanced smoothness, of the liner sidewalls 235e as compared to that of the opening sidewalls 204e—and correspondingly, to that of the opening sidewalls 104e of the prior art device 100—may, in certain embodiments, lead to reduced dimensional variations in the trench and/or via openings that will be formed in the dielectric material 201 during a later processing stage.

As may be appreciated, the degree and/or severity of the overall surface roughness, i.e., the line edge roughness, of the opening sidewalls 204e may depend on several material and/or device processing factors, each of which may contribute to one degree or another to the patterned opening sidewall surface variations described and illustrated above. For example, the actual line edge roughness severity may depend on, among other things, the type of material used for the hardmask 203 (e.g., a metal hardmask, a silicon-based dielectric hardmask, an organic hardmask, etc.), the grain size of the hardmask 203 (i.e., for a metal hardmask), the degree of reactivity of the hardmask 203 to the etch recipe that may be used to form the patterned openings 204, the length of exposure time to the etch recipe, and the like. Other factors may also influence the degree and/or severity of line edge roughness, and which may vary between the specific integration schemes used during device manufacturing.

In some illustrative embodiments of the present disclosure, the thickness 235t of the liner layer 235 may be selected as required based upon the degree and/or severity of the surface roughness of the sidewalls 204e. For example, a relatively “rougher” surface of the opening sidewalls 204e may necessitate a commensurately greater liner thickness 235t relative to the liner thickness 235t that may be required for sidewalls 204e that are less rough, or smoother, by comparison. Of course, experimental data for various combinations of processing parameters and device materials may be obtained so as to properly correlate a degree of surface roughness, e.g., of the sidewalls 204e, to a range of liner thicknesses 235t that may be necessary to provide the requisite degree of surface smoothness, e.g., of the sidewalls 235e, so as to thereby substantially reduce, or even eliminate, the dimensional variations of respective interconnect structures, as described and illustrated above.

In certain illustrative embodiments, the liner thickness 235t may range between approximately 2 nm and 5 nm, although greater or lesser thicknesses may also be used. In at least one embodiment, the liner thickness 235t may be approximately 3 nm, in which case the initial width 205a of the patterned openings 204 may be approximately 6 nm (i.e., approximately 2 times the liner thickness 235t) wide than the width 208 of the opening 207 to be formed in the dielectric material 201 (see, FIG. 2e).

Furthermore, in at least some embodiments, the material of the liner layer 235 may be selected so as to have an appropriately high etch selectivity relative to the material and/or materials that may make up the dielectric material 201, so that at least a portion of the liner layer 235 remains in place along the sidewalls 204e of the openings 204 during a later-performed etching process that is used to form the trench and/or via openings 207 (see, FIGS. 2d-2e). For example, the liner layer 235 may be made up of a suitable silicon-based dielectric material such as silicon nitride and the like, which is known to have a high etch selectivity relative to a standard oxide etch process that may be used etch openings in a silicon dioxide dielectric material layer, e.g., an ILD etch step. It should be understood, however, that other materials may also be used for the liner layer 235, provided the high degree of etch selectivity is maintained relative to the dielectric material 201. For example, in at least some embodiments of the present disclosure, the liner layer may be a silicon oxynitride material, and the like, as will be described in further detail below with respect to FIGS. 3a-3c and liner layer 335.

FIG. 2d schematically depicts the illustrative semiconductor device 200 of FIGS. 2b and 2d in a subsequent manufacturing stage, wherein an etch process 221 may be performed so as to remove portions of the liner layer 235 and the cap layer 202 from the bottom of each opening 204, thereby exposing an upper surface 201s of the dielectric material 201. Furthermore, portions of the liner layer 235 may also be removed from above the metal hardmask 203, thereby exposing the upper surface 203s. In certain embodiments, the etch process 221 may be, for example, a suitably designed anisotropic etch process, which may be adapted to remove only the horizontally oriented portions of the liner layer 235 from above the cap layer 202 and the metal hardmask 203, while leaving sidewall spacer portions 235s of the liner layer 235 that are present along the sidewalls 204e of the openings 204 substantially unaffected. In this way, the thickness 235t of the sidewall spacer portions 235s, and the reduced width 205b between the sidewall spacer portions 235s remain substantially unchanged, so that the critical dimension, or width, 208 of the trench and/or via openings 207 formed in the dielectric material 201 may meet the dimensional parameters established for the interconnect structures formed therein.

FIG. 2e schematically illustrates the semiconductor device 200 of FIG. 2d during yet a further manufacturing stage. As shown in FIG. 2e, the etch process 221 may be continued, and the metal hardmask 203 and the sidewall spacer portions 235s may be used an etch mask so as to form the openings 207, e.g., trench and/or via openings, in the dielectric material 201. In some embodiments, the etch recipe used for the etch process 221 may be adjusted as required from the previous processing stage—i.e., wherein the etch process was adapted to remove liner layer 235 and the cap layer 202 from the bottom of the openings 204—so as to selectively remove the specific material comprising the dielectric material 201. The openings 207 may have a width 208 that, in certain illustrative embodiments, may be substantially the same as the width 205b of the openings 204, which, due to the anisotropic nature of the etch process 221, may remain substantially unchanged throughout the duration of the etch process 221.

In certain embodiments, the sidewalls 207e of the openings 207 may be substantially self-aligned with the sidewalls 235e of the sidewall spacer portions 235s. Furthermore, in at least some embodiments, the sidewalls 207e may have a substantially vertical orientation, e.g., substantially perpendicular to the upper surface 201s of the dielectric material 201, so that the width 208 of the openings 207 is substantially the same as the width 205b of the patterned openings 204. Moreover, due to the reduced surface roughness, i.e., the enhanced surface smoothness, of the sidewalls 235e as shown in FIG. 2c, the sidewalls 207e of the openings 207 may be substantially smoother and straighter than the corresponding sidewalls 107e of the openings 107 in the prior art semiconductor device 100. Moreover, the likelihood that localized dimensional variations may occur in the widths 208 of the openings 207 or the spaces 209 therebetween—as is shown for the widths 108 and spaces 109 in FIG. 1d and described above—may be substantially reduced, or even eliminated, due to presence of the reduced surface roughness sidewall spacer portions 235s in the openings 204, and the commensurately reduced line edge roughness of the lined openings 204.

In another illustrative embodiment of the present disclosure, a liner layer having a reduced surface roughness may be used inside of one or more patterned opening of a hardmask layer so as to form openings in a dielectric material that may be substantially less likely to have detrimental dimensional variations as previously described with respect to the prior art process illustrated in FIGS. 1a-1g, wherein the openings in the dielectric material may have a tapered opening shape that may serve to facilitate a more complete and substantially void-free filling of the openings during a subsequent conductive fill process. An illustrative method that may be used to form more fill-friendly openings in a dielectric material, such as the tapered openings described above, is schematically illustrated in FIGS. 3a-3c and described below.

FIG. 3a schematically illustrates a semiconductor device 300 during a manufacturing stage that is similar to that shown in FIG. 2b, as described above. The semiconductor device 300 may include, among other things, a patterned metal hardmask 303 formed above a dielectric material 301, wherein a plurality of patterned openings 304 have been formed in the metal hardmask 303. In certain embodiments, a cap layer 302 may be positioned between the metal hardmask 303 and the underlying dielectric material 301, which may act as an etch stop layer during the formation of the openings 304.

As shown in FIG. 3a, a deposition process 320, such as a conformal CVD or ALD process as previously described, may be performed so as to form a substantially conformal liner layer 335 above the semiconductor device 300. As with previously described liner layer 235, the liner layer 335 has sidewall surfaces 335e which, in some illustrative embodiments, may have a substantially reduced line edge roughness as compared to the surface roughness of the initial sidewalls surfaces 304e of the patterned openings 304. See, e.g., the comparative surface roughness of the sidewalls 204e and 235e as shown in the illustrative embodiments depicted in FIGS. 2b-2c and described above. Furthermore, the openings 304 may be spaced in the metal hardmask 303 on a pitch 305p such that the sidewalls 335e of the liner layer 335 formed along the sidewalls 304e of adjacent openings 304 are separated by a space 306b.

However, unlike the thickness 235t of the liner layer 235 formed above the semiconductor device 200, in some embodiments disclosed herein, the liner layer 335 may have an initial thickness 335t that may be established such that the reduced-size width 305b of the opening 304 may be smaller than a targeted nominal width of a trench and/or via opening to be formed in the dielectric material 301 during a subsequent processing step, such as the width 308 of the openings 307 shown in FIG. 3c. In such embodiments, the thickness 335t may be reduced during a later-performed etch process that may be used to form the trench and/or via openings in the dielectric material 301, which may thus lead to forming openings, such as the openings 307 of FIG. 3c, in the dielectric material 301 with a slightly enhanced tapered shape, as will be further described below. Accordingly, when a certain liner thickness may be necessary so as to reduce the surface roughness of the opening sidewalls 304e by a requisite amount (as described with respect to the thickness 235t above), the liner thickness 335t may established with an additional thickness so as to account for the thickness reduction of the liner layer 335 during the etching process used to form the tapered openings 307.

The amount of additional liner thickness included in the as-deposited liner thickness 335t may depend on several factors, including, among other things, the desired degree of opening taper, the degree of etch resistance that the material of the liner layer 335 may have to a specified etch recipe, the desired depth of the tapered openings, and the like. For example, when a liner thickness of approximately 3 nm is required to reduce the line edge roughness of the sidewall 304e, the as-formed liner thickness 335t may be slightly greater, such as approximately 5-6 nm, although other thicknesses may be used in view of at least some of the factors outlined above.

Furthermore, in certain embodiments, the material of the liner layer 335 may be selected so as to have a lesser degree of etch selectivity relative to the dielectric material 301, as compared to the relatively high degree of etch selectivity that may be displayed by the material of the liner layer 235 formed above the semiconductor device 200 as described above. For example, in at least some embodiments, the material of the liner layer 335 may be a silicon oxynitride material and the like, which under certain conditions may have less of an etch resistance when exposed to a conventional oxide/ILD etch recipe than, for example, a silicon nitride material, i.e., one illustrative highly selective material that may be used to form the liner layer 235 of the semiconductor device 200 shown in FIGS. 2a-2e above.

FIG. 3b schematically depicts the illustrative semiconductor device 300 of FIG. 3a in a further manufacturing stage, wherein an etch process 321 may be performed so as to remove portions of the liner layer 335 and the cap layer 302 from the bottom of each opening 204, thereby exposing an upper surface 301s of the dielectric material 301. Additionally, portions of the liner layer 335 may be removed from above the metal hardmask 303 so as to thereby expose the upper surface 303s thereof. In at least some embodiments, the etch process 321 may be, for example, a substantially anisotropic etch process that may primarily be adapted to remove the horizontally oriented portions of the liner layer 335 from above the cap layer 302 and the metal hardmask 303, while leaving sidewall spacer portions 335s of the liner layer 335 along the sidewalls 304e of the openings 304.

While the etch process 321 may be substantially anisotropic in nature, in at least some illustrative embodiments, the etch process 321 may also be adapted, together in some cases with the specific material of the liner layer 335, to also have at least some effect on the thickness of the sidewall spacer portions 335s that are present along the sidewalls 304e of the openings 304, as previously described. Accordingly, in certain embodiments, such as the illustrative embodiment depicted in FIG. 3b, the sidewall spacer portions 335s may have a reduced thickness 335b at an upper end 335u thereof that may be less than the as-deposited liner thickness 335t, thereby resulting in a width 305b of the openings 304 at the upper ends 335u of the sidewall spacer portions 335s that is greater than the width 305a as shown in FIG. 3a. Furthermore, due to the partial etching of the sidewall spacer portions 335s, the sidewalls 335e may be tapered, e.g., substantially not perpendicular to the upper surface 301s of the dielectric material 301, such that a width 302b of the openings 304 at the upper surface 301s is less than the width 305b at the upper ends 335u of the sidewall spacer portions 335s.

FIG. 3c shows the illustrative semiconductor device 300 in a subsequent manufacturing stage, wherein the etch process 321 may be continued, and wherein the metal hardmask 303 and the sidewall spacer portions 335s may be used as an etch mask so as to form tapered openings 307 in the dielectric material 301. In certain embodiments, the etch recipe used for the etch process 321 may be adjusted as required from the previous processing step so as to etch the material of the dielectric 301, such as to a conventional oxide or ILD etch recipe, and the like. As shown in FIG. 3c, and due at least in part to the continuous effect that the adjusted etch recipe of the etch process 321 may have on the thickness of the sidewall spacer portions 335s, a thickness 335c at the upper ends 335u thereof may now be less than the thickness 335b as shown in FIG. 3b during the previous processing step. Furthermore, the width 305c of the opening 304 at the upper ends 335u of the sidewall spacer portions 335s is commensurately increased above the previous width 305b relative to the reduced thickness 335c. Additionally, the width 302c of the opening 307 at the upper surface 301s of the dielectric material 301 is similarly increased relative to the previous width 302b. However, due to the tapered configuration of the sidewalls 335e, the width 302c at the dielectric material surface 301s is still less than the width 305c at the upper ends 335u of the sidewall spacer portions 335s.

As noted previously, the etch recipe of the etch process 321 may be continuously reducing the thickness of the sidewall spacer portions 335s throughout the etch process 321, thereby resulting in substantially tapered sidewalls 335e. Due to this same effect, in some illustrative embodiments of the present disclosure, the sidewalls 307e of the openings 307 may also have a substantially tapered configuration, e.g., substantially not perpendicular to the upper surface 301s of the dielectric material 301, such that width 308 at the bottom of the opening 307 is less than the width 302c at the top of the opening. In this way, the generally tapered shape of the opening 307 may provide a more fill-friendly profile when, for example, a physical vapor deposition (PVD) process may be used to fill the openings 307 with a conductive material during a subsequent manufacturing stage. Furthermore, the amount of taper present in the sidewalls 307e may be adjusted such that the width 308 and the space 309 between adjacent openings 307 may result in an appropriate electrical behavior of the conductive structures that will be formed in the openings 307. For example, in those illustrative embodiments wherein the liner layer 335 is made of a silicon nitride material, the etch resistance of the liner layer 335 to a conventional oxide etch recipe may be incrementally reduced as the oxygen content of the silicon nitride material of the liner layer 335 is correspondingly increased. Accordingly, the oxygen content, and corresponding etch resistivity, of the liner layer 335 may be adjusted as noted above so as to influence the amount of taper that may be present in the sidewalls 335e, and therefore in the sidewalls 307e. It should also be appreciated that, due at least in part to the reduced surface roughness of the sidewall spacer portions 335s, i.e., the reduced line edge roughness of the lined openings 304, the likelihood that the sidewalls 307e of the openings 307 might display the surface and dimensional irregularities found in the prior art device 100 may be substantially decreased, or even eliminated altogether.

As a result of the presently disclosed subject matter, various methods are described for forming a liner layer above a patterned hardmask layer and using the liner layer as an etch mask so as to reduce line edge roughness in hardmask integration schemes that are used for forming interconnect structures, such as conductive lines and/or conductive vias, in an underlying dielectric material.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

1. A method, comprising:
forming a metal hardmask above a dielectric material;
forming a first opening in said metal hardmask, said first opening comprising sidewalls, said sidewalls having a surface roughness;
reducing said surface roughness of said sidewalls, wherein reducing said surface roughness comprises forming a liner layer inside of said first opening and removing a portion of said liner layer from above a bottom of said first opening so as to form spacers along said sidewalls, wherein an exposed surface of said spacers has said reduced surface roughness; and
using said first opening with said sidewalls of reduced surface roughness to form a second opening in said dielectric material.

2. (canceled)

3. (canceled)

4. The method of claim 1, wherein forming said liner layer comprises performing a conformal material deposition process to form a substantially conformal material layer.

5. The method of claim 1, wherein forming said second opening in said dielectric material comprises using said spacers as an etch mask and performing an etch process to selectively remove a portion of said dielectric material below said first opening.

6. The method of claim 5, wherein forming said second opening in said dielectric material comprises forming a substantially tapered opening.

7. The method of claim 6, wherein forming said substantially tapered opening comprises reducing a thickness of said spacer during said etch process.

8. The method of claim 1, further comprising forming a cap layer above said dielectric material prior to forming said hardmask and using said cap layer as an etch stop layer when forming said first opening.

9. The method of claim 1, wherein forming said metal hardmask comprises forming a material layer comprising titanium nitride.

10. A method, comprising:
forming a patterned metal hardmask above a dielectric material layer, said patterned metal hardmask comprising a patterned opening;
depositing a conformal material layer above said patterned metal hardmask;
forming sidewall spacers on sidewalls of said patterned opening from said conformal material layer by performing an etch process to remove at least a portion of said conformal material layer that is formed above a bottom surface of said patterned opening; and
using said sidewall spacers as an etch mask to form one of a trench opening and a via opening in said dielectric material layer below said patterned opening.

11. (canceled)

12. The method of claim 10, wherein depositing said conformal material layer comprises performing one of a chemical vapor deposition process and an atomic layer deposition process.

13. The method of claim 10, wherein depositing said conformal material layer comprises depositing a material layer having a thickness that is approximately 3 nm or less.

14. The method of claim 10, wherein said patterned opening is formed in said patterned metal hardmask having a width that is greater than a width of said one of a trench opening and a via opening by approximately 2 times a thickness of said conformal material layer.

15. The method of claim 10, wherein sidewalls of said one of a trench opening and a via opening are substantially aligned with inside sidewall surfaces of said sidewall spacers.

16. The method of claim 10, wherein sidewalls of said one of a trench opening and a via opening are substantially not perpendicular to an upper surface of said dielectric material layer.

17. The method of claim 16, further comprising performing a physical vapor deposition process to fill said one of a trench opening and a via opening with a conductive material.

18. The method of claim 10, wherein a thickness of said sidewall spacers remains substantially unchanged throughout an etch process that is used to form said one of a trench opening and a via opening.

19. The method of claim 10, wherein a thickness of said sidewall spacers is continuously reduced throughout an etch process that is used to form said one of a trench opening and a via opening.

20. A method, comprising:
forming a metal hardmask above a layer of dielectric material;
forming a patterned opening in said metal hardmask so as to expose a portion of a cap layer formed above said layer of dielectric material, said patterned opening comprising exposed sidewalls having a first surface roughness;
forming a layer of spacer material at least on said exposed sidewalls of said patterned opening and above said exposed portion of said cap layer;
forming sidewall spacers on said exposed sidewalls of said patterned opening from said layer of spacer material by removing at least a portion of said layer of spacer material from above said cap layer, wherein an exposed surface of said sidewall spacers has a reduced surface roughness as compared to said first surface roughness; and
forming at least one of a trench opening and a via opening in said layer of dielectric material using said sidewall spacers as an etch mask.

21. The method of claim 20, wherein forming said metal hardmask comprises forming a titanium nitride material layer that does not contain carbon.

22. The method of claim 1, wherein forming said metal hardmask comprises forming a material layer that does not contain carbon.

23. The method of claim 10, wherein forming said patterned metal hardmask comprises forming a titanium nitride material layer that does not contain carbon.
